(19) United States
(12) Patent Application Publication
(10) Pub. No.: US 2026/0196250 A1
(43) Pub. Date: Jul. 9, 2026

(54) FEOL AND BEOL-AWARE MEMORY CELL BUILD

(71) Applicant: International Business Machines Corporation, Armonk, NY (US)

(72) Inventors: Ananth Nag Raja DARLA, Bangalore (IN); Michael LEE, Austin, TX (US); Shankar KALYANASUNDARAM, Bengaluru (IN); Dinesh Reddy RANGAREDDYGARI, Puttaparthi (IN)

(21) Appl. No.: 19/014,897

(22) Filed: Jan. 9, 2025

(51) Int. Cl. G11C 5/06; G11C 11/419

(52) U.S. Cl. CPC G11C 5/063; G11C 11/419

(57) ABSTRACT

Techniques are described for designing a multiport memory cell (e.g., a multiport SRAM memory cell, or a register file cell) for an integrated circuit (IC). The design techniques can balance between a front end of line (FEOL) design of the memory cell and a back end of line (BEOL) design of the memory cell. Once the FEOL design of the memory cell is complete, the BEOL design can be performed where the metal routing layers that transmit the control and data signals of the memory cell are designed. The resistive-capacitive (RC) characteristics of the metal layers in the BEOL design can be checked to determine if they satisfy performance thresholds. If not, the metal layers can be redesigned (e.g., increasing the width of the metal traces, or using different metal layers) which can have an effect on the size of the cell determined in the FEOL.

### BACKGROUND

The present invention relates to memory cell design for an integrated circuit.

### SUMMARY

According to one embodiment of the present invention, a method includes generating, using an integrated circuit (IC) design application executing in a processor, a front end of line (FEOL) memory cell design where the FEOL memory cell design is for a multiport memory cell; designing, using the IC design application, metal routing layers in a back end of line (BEOL); determining, using the IC design application, resistive-capacitive (RC) characteristics between the metal routing layers; upon determining the RC characteristics and the FEOL memory cell design are unbalanced, adjusting at least one of the metal routing layer or dimensions of the FEOL memory cell design.

According to one embodiment of the present invention, a system includes one or more processors and memory storing one or more applications which, when executed by the one or more processors, perform operations. The operations comprise generating, using an IC design application executing in a processor, a FEOL memory cell design where the FEOL memory cell design is for a multiport memory cell; designing, using the IC design application, metal routing layers in a BEOL; determining, using the IC design application, RC characteristics between the metal routing layers; and upon determining the RC characteristics and the FEOL memory cell design are unbalanced, adjusting at least one of the metal routing layer or dimensions of the FEOL memory cell design.

According to one embodiment of the present invention, a computer program product that includes one or more computer readable storage media and program instructions stored on the one or more computer readable storage media to perform operations. The operations comprise generating, using an IC design application executing in a processor, a FEOL memory cell design where the FEOL memory cell design is for a multiport memory cell; designing, using the IC design application, metal routing layers in a BEOL; determining, using the IC design application, RC characteristics between the metal routing layers; and upon determining the RC characteristics and the FEOL memory cell design are unbalanced, adjusting at least one of the metal routing layer or dimensions of the FEOL memory cell design.

### BRIEF DESCRIPTION OF THE DRAWINGS

FIG. 1 illustrates a computing environment, according to one embodiment described herein.

FIG. 2 illustrates circuit components in a memory cell, according to one embodiment described herein.

FIG. 3 is a flowchart for designing a memory cell at a front end of line (FEOL), according to one embodiment described herein.

FIG. 4 is a FEOL memory cell design, according to one embodiment described herein.

FIG. 5 is a FEOL memory cell design, according to one embodiment described herein.

FIG. 6 is a flowchart for designing a memory cell at a back end of line (BEOL), according to one embodiment described herein.

FIGS. 7A and 7B illustrate metal layers containing vertical traces, according to embodiments described herein.

FIGS. 8A and 8B illustrate metal layers containing horizontal traces, according to embodiments described herein.

### DETAILED DESCRIPTION

The embodiments herein describe techniques for designing a multiport memory cell (e.g., a multiport SRAM memory cell, or a register file cell) for an integrated circuit (IC) or semiconductor chip. The multiport memory cell can be modular so it can be replicated and used in many places in the IC. The design techniques can balance between a FEOL design of the memory cell and the BEOL design. During FEOL design, the core components of the memory cell (e.g., latch, inverter, write ports, read ports, etc.) can be placed within the area constraints of the cell (e.g., a width and length in the IC). Once the FEOL design of the memory cell is complete, the BEOL can be performed where the metal routing layers that transmit the control and data signals of the memory cell are designed. The resistive-capacitive (RC) characteristics of the metal layers in the BEOL can be checked to determine if they satisfy performance thresholds. If not, the metal layers can be redesigned (e.g., increasing the width of the metal traces, or using different metal layers). However, this can have an effect on the size of the cell determined in the FEOL. Thus, the changes performed on the metal layers in the BEOL can be balanced with the FEOL design (e.g., where increasing the width of the metal traces in the metal layers increases the size of the memory cell in the FEOL).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods using an IC design application 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

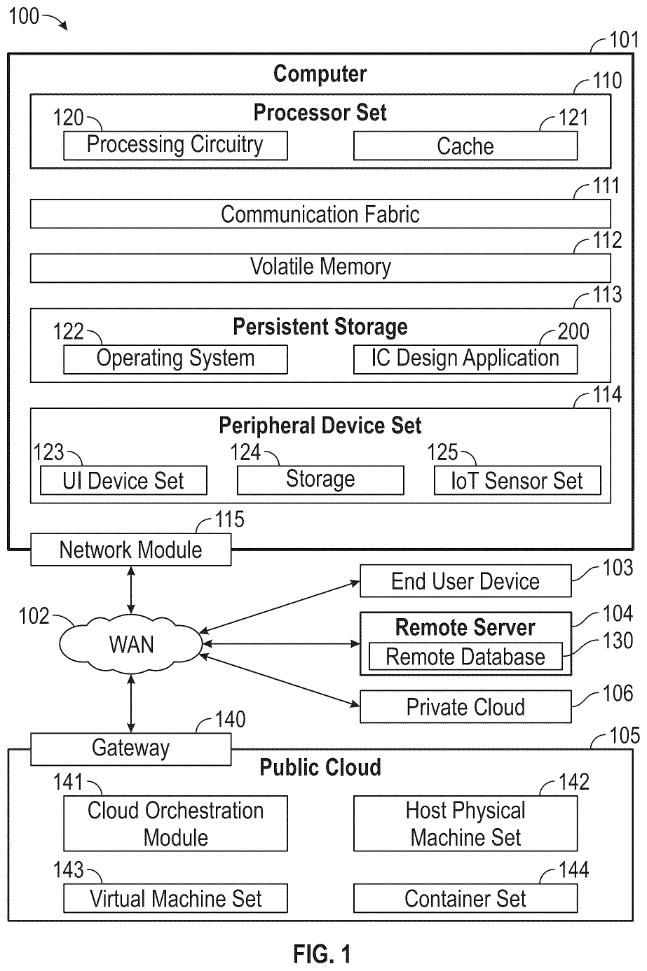

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not separately shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to as “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

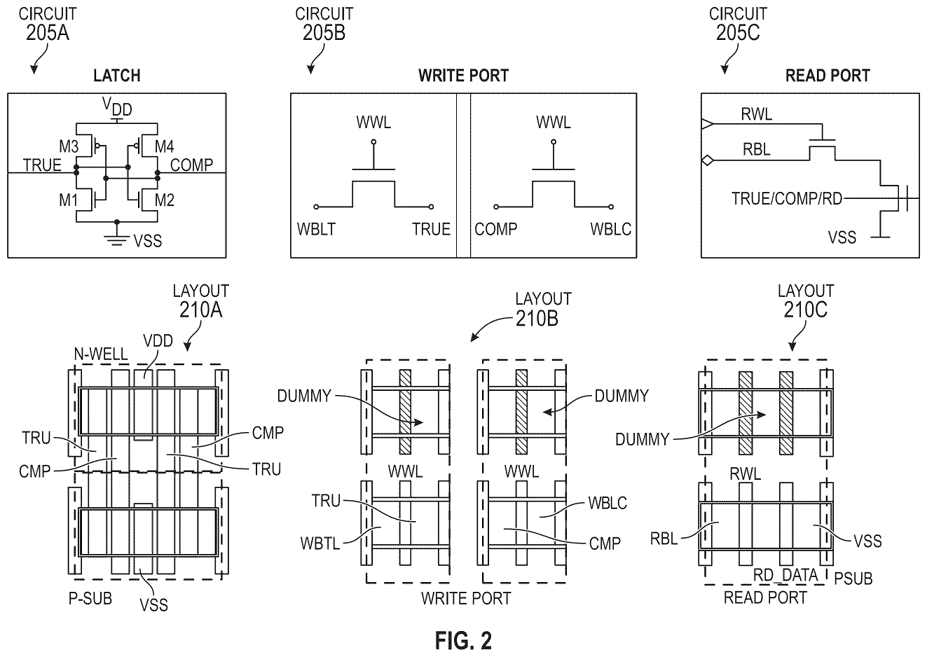

FIG. 2 illustrates circuit components in a memory cell, according to one embodiment described herein. In this example, a memory cell (e.g., a multiport SRAM cell or a modular register file cell) can be formed from a latch (which includes back-to-back inverters), a write port, and a read port. The circuit 205A illustrates an exemplary circuit design for the latch, the circuit 205B illustrates an exemplary circuit design for write ports, and the circuit 205C illustrates an exemplary circuit design for the read port. In this example, the circuit 205A indicates the latch includes both PMOS and NMOS devices, while the write and read ports only include NMOS devices. Moreover, the NMOs transistors in the circuit 205A are labeled as M1 and M2, while the PMOS transistors are labeled M3 and M4. The circuit 205A also includes the TRUE and complimentary (COMP) signals.

The circuit 305B illustrates two NMOS transistors that receive the signals write word line (WWL), write bit line true (WBLT), TRUE, COMP, and the write bit line complimentary (WBLC).

The circuit 305C illustrates two NMOS transistors that receive the signals read word line (RWL), read bit line (RBL), and TRUE/COMP/read (RD).

FIG. 2 also illustrates exemplary layouts of the latch, write port, and read ports in an IC. That is, the layout 210A illustrates an exemplary layout for the latch, the layout 210B illustrates an exemplary layout for the write ports, and the layout 210C illustrates an exemplary layout for the read port. The layout 210A for the latch shows that one half of the layout is in an N-well (e.g., a N-doped region of the IC) while the remaining half of the layout is in a P-doped substrate. That is, FIG. 2 assumes that the substrate of the IC is doped P, but regions are doped more heavily N type to form the N-well. The N-well is where the PMOS transistors of the circuit 205A are formed since they use N-doped silicon. In contrast, the layout 210B for the two write ports and the layout 210C for the read port are disposed solely in the P-substrate (and not in a N-well) since they include NMOS transistors. While the embodiments herein discuss a P-doped substrate and N-wells, the embodiments herein could also be used with an IC with an N-doped substrate that is doped to include P-wells. Thus, the doped-wells can be doped oppositely of the substrate of the IC.

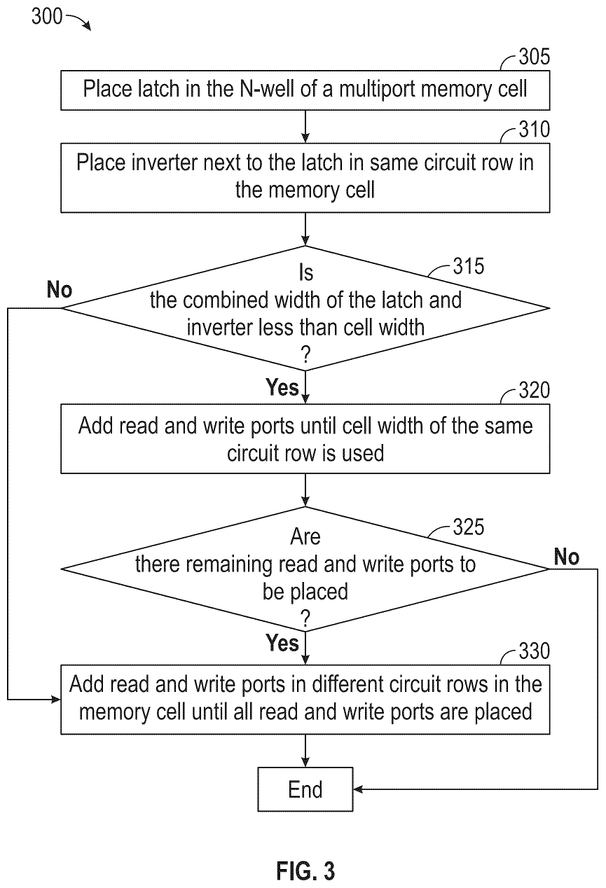

FIG. 3 is a flowchart of a method 300 for designing a memory cell at a FEOL, according to one embodiment described herein. The FEOL is the first portion of IC fabrication where the individual components (transistors, capacitors, resistors, etc.) are patterned in a semiconductor substrate. FEOL generally covers everything up to (but not including) the deposition of metal interconnect layers. The method 300 is used to generate a cell design that can be used during the FEOL when fabricating an IC.

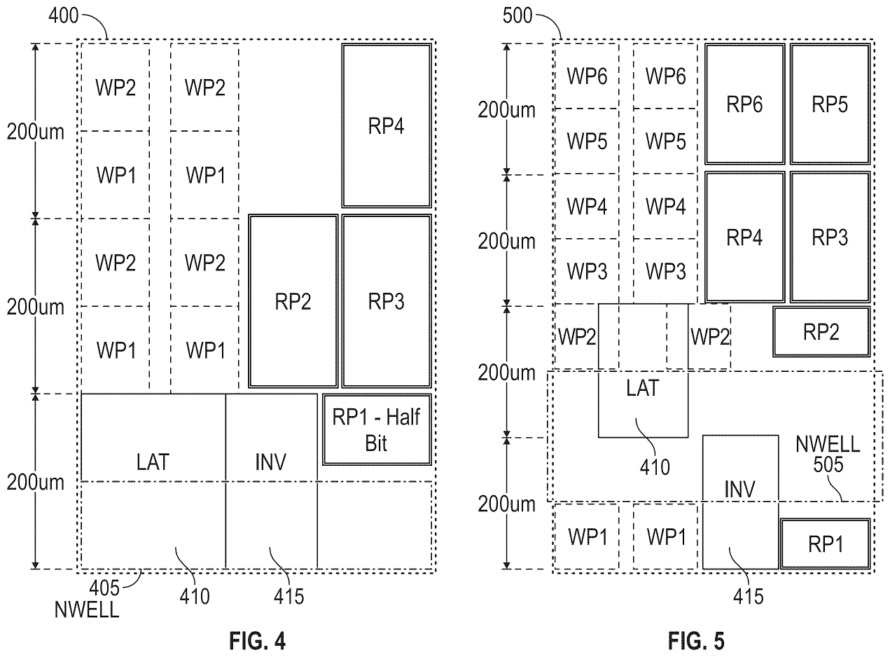

Moreover, for clarity, the blocks of the method 300 are discussed in tandem with FIGS. 4 and 5 which illustrate FEOL memory cell designs, according to embodiments described herein.

At block 305, the designer uses the IC design application (e.g., the IC design application 200 in FIG. 1) to place a latch at least partially in the N-well of a multiport memory cell. As shown in FIG. 4, a memory cell 400 includes a NWELL 405 where a latch (LAT) 410 is disposed. Here, half of the latch 410 is in the NWELL 405 while the remaining half of the latch 410 is in the P-doped substrate. This is because half of the transistors in the latch 410 are PMOS, and thus, use the NWELL 405 while the other half are NMOS and use the P-doped substrate (as discussed in FIG. 2).

Moreover, the cell 400 also illustrates that the NWELL 405 is disposed along a border of the cell 400. In one embodiment, the NWELL 405 can be shared where the NWELL 405 can extend into a neighboring cell (e.g., a cell disposed at the bottom of the cell 400). Having an NWELL that extends across cell boundaries can be a more efficient use of space, and thus, reduce the area of the memory cells.

FIG. 5 illustrates a memory cell 500 that includes a NWELL 505 where again half of the latch 410 is disposed in the NWELL 505. However, the NWELL 505 may not be shared with a cell disposed at the bottom of the cell 500 since the NWELL 505 does not extend to the bottom side of the cell 500.

Returning to method 300, at block 310 the designer uses the IC design application to place an inverter next to the latch in the same circuit row in the memory cell. This is illustrated in FIGS. 4 and 5 where inverters 415 (INV) are disposed next to the latches 410 in the horizontal direction. In FIG. 4, the latch 410 and the inverter 415 are disposed side-by-side. In FIG. 5, the latch 410 and inverter 415 are disposed at an offset, but are still considered as being in the same circuit row.

Like the latches 410, the inverters 415 also can include both PMOS and NMOS transistors. As such, at least some portions of the inverters 415 (half in this case) are disposed in the NWELLs while the remaining portions are in the P-doped substrate.

Returning to method 300, at block 315 the designer determines whether the combined width of the latch and inverters is less than the width of the memory cell. If so, this means there is additional room in the row that includes the latch and inverter, which can be used for placing read and/or write ports.

In that case, the method 300 proceeds to block 320 where the designer uses the IC design application to add read and write ports until the cell width of the same circuit row that includes the latch and inverter is used. In FIG. 4, there is sufficient space for one read port (a half bit of RP1) to be added in the same row that includes the latch 410 and inverter 415. In FIG. 5, there is sufficient space for two write ports (WP1 and WP2) and two read ports (RP1 and RP2) to be added in the same row that includes the latch 410 and inverter 415.

The method 300 then proceeds to block 325 where the designer determines whether there are remaining read and write ports to be placed. In method 300, it is assumed that the designer has already established how many read and write ports the memory cell should have (e.g., 1 read, 1 write (1R1W), two read, two write (2R2W), . . . N read, N write). As such, the designer can determine how many of the desired read and write ports are remaining to be placed in the memory cell.

If there are remaining read or write ports that have not yet been placed, the method 300 proceeds to block 330 where the designer adds read and write ports in different circuit rows in the memory cell until each read and write ports is placed. That is, since the space in the row that includes the latch and the inverter has already been taken up at blocks 305-320, the designer can use the IC design application to place any remaining read and write ports in other rows in the memory cell. For example, FIG. 4 illustrates placing write ports WP1, WP2 and read ports RP2, RP3, RP4 in rows above the row containing the latch 410 and the inverter 415. FIG. 5 illustrates placing write ports WP3, WP4, WP5, WP6 and read ports RP3, RP4, RP, RP6 in rows above the row containing the latch 410 and the inverter 415. Moreover, the rows can be in the P-substrate region of the cell since the read and write ports may contain only NMOS transistors.

Notably, if at block 315 there was no additional room in the row that contains the latch and inverter, the method 300 proceeds directly to block 330 where additional rows in the memory cell are used to place the read and write ports.

Moreover, if at block 325 the designer was able to place all the read and write ports in the same row that contains the latch and inverter, the method 300 can end (i.e., omit block 330).

At the end of the method 300, the memory cell 400 in FIG. 4 has the circuit components to be a four read, four write (4R4W), ten poly pitch (10PC) 3Bits memory cell. That is, the memory cell 400 can perform four reads in parallel, or four writes in parallel. The memory cell 500 in FIG. 5 has the circuit components to be six read and six write (6R6W), 12 poly pitch (12PC) 4Bits memory cell. That is, the memory cell 500 can perform six reads in parallel or six writes in parallel.

The memory cell designed using the method 300 can then be used to fabricate the cell in a FEOL process and thus is referred to as a FEOL memory cell design. However, as mentioned above, this FEOL memory cell design can be balanced with the metal routing layers that are part of BEOL design.

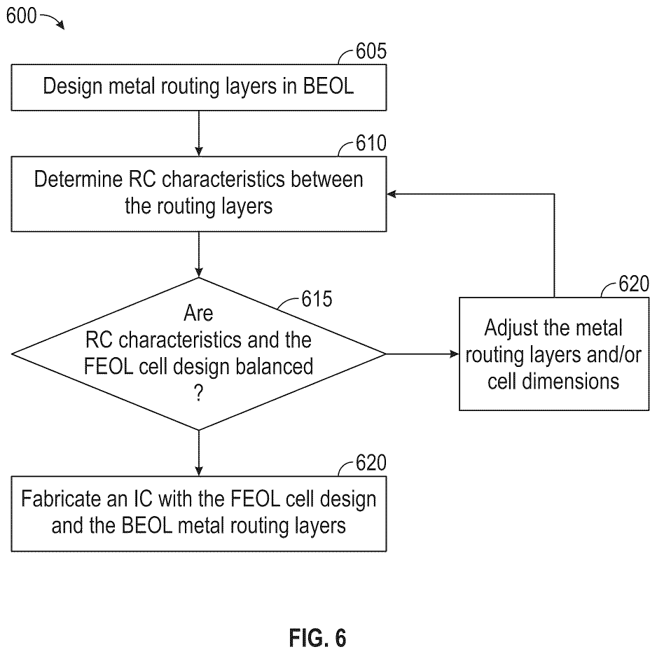

FIG. 6 is a flowchart of a method 600 for designing a memory cell for a BEOL design, according to one embodiment described herein. BEOL is a process in semiconductor device fabrication that includes depositing metal interconnect layers onto a wafer already patterned with devices (e.g., transistors, capacitors, resistors, etc.). It is the second part of IC fabrication, after FEOL, or a third part of IC fabrication if there is a middle end of line (MEOL). In BEOL, the individual devices formed in the FEOL (and MEOL) are connected to each other according to how the metal wiring is deposited. The BEOL design often includes multiple metal routing layers that are formed on the devices, and are connected to the devices using vias.

At block 605, the designer uses the IC design application to design metal routing layers in BEOL design. In one embodiment, the metal routing layers in the BEOL are linked with the FEOL cell design to make the memory cell modular—e.g., so the cell can be replicated and placed at multiple locations within the overall IC design.

In one embodiment, the designer uses lower writing resources (e.g., metal layer 2) and a minimum width to connect local bit lines (LBL) to the cell circuitry. For RWL and WWL, the designer can consider write bit lines (WBL) and assign two pairs of WBLs in two different metal layers (e.g., metal layer 3 and metal layer 5). In addition, the designer can consider global bit lines (GBL) to be used with a half shield.

Some BEOL constraints can include Metal RC variations in PDKs, metal pitch, consistency of WL and BL widths to close timing and for better performance, reducing RC difference when having WLs/BLs in different metals, and global and solar bitlines can be considered.

At block 610, the designer uses the IC design application to check RC characteristics between routing layers. The RC characteristics can be based on the spacing between the metal routing layers (if they are disposed on neighboring layers), the number of traces in each layer, and the width of the traces.

At block 615, the designer uses the IC design application to determine whether the RC characteristics and the FEOL cell design are balanced. In one embodiment, balancing the BEOL metal layers and FEOL cell design can mean that the RC characteristics of the metal layers in the BEOL satisfy a performance threshold with the current dimensions of the FEOL memory cell. For example, the FEOL cell design and the BEOL metal layers may be unbalanced if the metal layers cannot meet the RC characteristics using the area of the FEOL cell design as a constraint (as defined by the current dimensions of the cell).

Assuming the RC characteristics and FEOL cell design are unbalanced, the method 300 proceeds to block 620 where the designer uses the IC design application to adjust the metal routing layers or the dimensions of the FEOL cell design. For example, the designer may use lower metal, like metal layer 2 in the scenario where metal layer 4 or metal layer 6 do not have available wiring resources. Or the designer may widen the traces in metal layer 2 based on the RC characteristics that match higher metal layers. In response to adjusting the metal routing layers, the dimension (e.g., width) of the memory cell of the FEOL design may increase. For example, increasing the width of the traces in the BEOL metal layers may inherently increase the size of the FEOL memory cell.

The method 600 can then return to block 610 were the RC characteristics are re-checked and at block 615 the designer can determine whether the RC characteristics are now balanced with the FEOL cell design.

If so, the method 600 proceeds to block 620 where the IC is fabricated using the FEOL cell design and the BEOL metal routing layers. Moreover, in one embodiment, the FEOL cell design and the BEOL metal routing layers can be modularized.

Moreover, the methods 300 and 600 in FIGS. 3 and 6 can be performed by a human (e.g., a designer) that uses the IC design application or automatically by the IC design application. Thus, the blocks in methods 300 and 600 can be performed programmatically without human input.

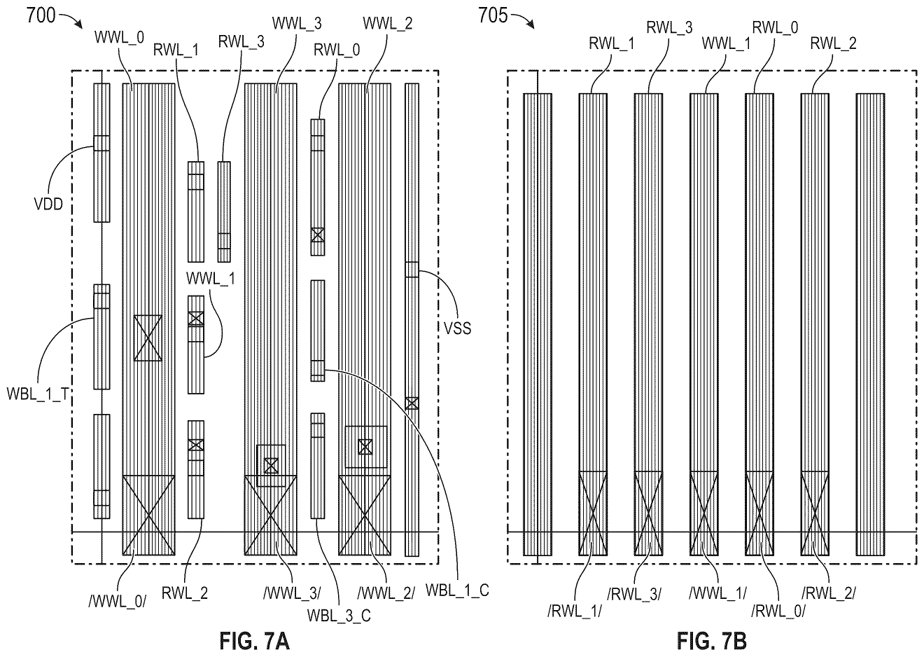

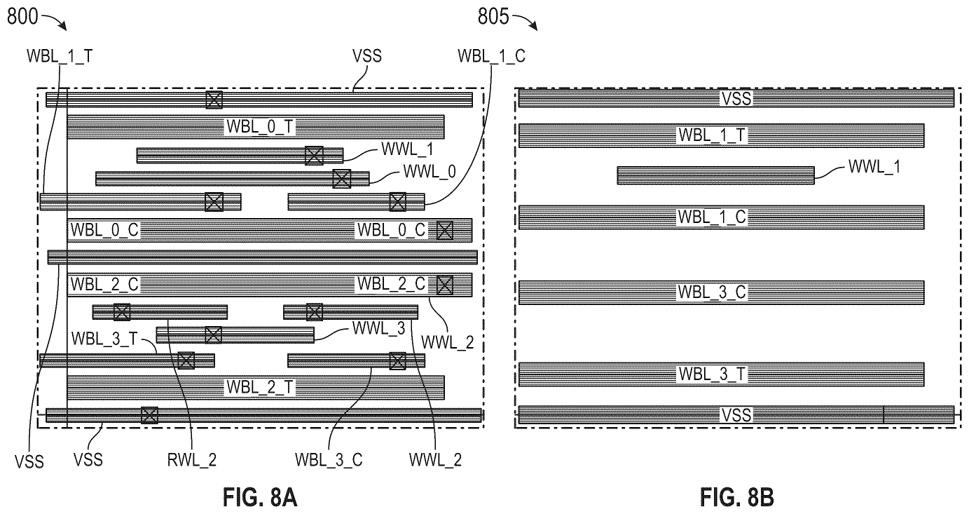

FIGS. 7 and 8 illustrate different metal layouts that can result from performing method 600. Specifically, FIGS. 7A and 7B illustrate metal layers 700 and 705 containing vertical traces, while FIGS. 8A and 8B illustrate metal layers 800 and 805 containing horizontal traces. The metal traces in FIG. 7A can be disposed on a different metal layer than the metal traces in FIG. 7B. Further, the metal traces in FIG. 8A can be disposed on a different metal layer than the metal traces in FIG. 8B. In one example, FIGS. 7 and 8 illustrate four different metal layers that can be used to route signals to the circuitry in the cell 400 in FIG. 4. These metal layers and the cell 400 can then be used to modularize the memory cell.

While the foregoing is directed to embodiments of the present invention, other and further embodiments of the invention may be devised without departing from the basic scope thereof, and the scope thereof is determined by the claims that follow.

What is claimed is:

1. A method comprising:
generating, using an integrated circuit (IC) design application executing in a processor, a front end of line (FEOL) memory cell design, wherein the FEOL memory cell design is for a multiport memory cell;
designing, using the IC design application, metal routing layers in a back end of line (BEOL) design;
determining, using the IC design application, resistive-capacitive (RC) characteristics between the metal routing layers; and
upon determining the RC characteristics and the FEOL memory cell design are unbalanced, adjusting at least one of the metal routing layers in the BEOL design or dimensions of the FEOL memory cell design.

2. The method of claim 1, further comprising:
fabricating an IC based on the metal routing layers in the BEOL design and the FEOL memory cell design.

3. The method of claim 1, further comprising:
linking the metal routing layers in the BEOL design to the FEOL memory cell design to make the multiport memory cell modular.

4. The method of claim 1, wherein generating the FEOL memory cell design comprises:
placing a latch in a doped well in a cell for the FEOL memory cell design, wherein the doped well is doped oppositely than a substrate of an IC to be fabricated based on the FEOL memory cell design; and
placing an inverter in a same circuit row of the cell as the latch.

5. The method of claim 4, wherein part of the latch and part of the inverter are disposed in the substrate of the IC while remaining portions of the latch and the inverter are disposed in the doped well.

6. The method of claim 4, wherein generating the FEOL memory cell design comprises:
determining that a combined length of the latch and inverter is less than a width of the cell; and
adding at least one read or write port to the same circuit row.

7. The method of claim 6, wherein generating the FEOL memory cell design comprises:
determining that no more read or write ports can be added to the same circuit row;
determining there are remaining read and write ports that should be added to the cell; and
adding the remaining read and write ports in one or more different circuit rows in the cell.

8. The method of claim 1, wherein the RC characteristics and the FEOL memory cell design are balanced when the RC characteristics of the metal routing layers in the BEOL satisfy a performance threshold with current dimensions of the FEOL memory cell design.

9. A system, comprising:
one or more processors; and
memory storing one or more applications which, when executed by the one or more processors, perform operations comprising:
generating, using an integrated circuit (IC) design application executing in a processor, a front end of line (FEOL) memory cell design, wherein the FEOL memory cell design is for a multiport memory cell;
designing, using the IC design application, metal routing layers in a back end of line (BEOL) design;
determining, using the IC design application, resistive-capacitive (RC) characteristics between the metal routing layers; and
upon determining the RC characteristics and the FEOL memory cell design are unbalanced, adjusting at least one of the metal routing layer or dimensions of the FEOL memory cell design.

10. The system of claim 9, wherein the operations comprise:
fabricating an IC based on the metal routing layers in the BEOL design and the FEOL memory cell design.

11. The system of claim 9, wherein the operations comprise:
linking the metal routing layers in the BEOL design to the FEOL memory cell design to make the multiport memory cell modular.

12. The system of claim 9, wherein generating the FEOL memory cell design comprises:
placing a latch in a doped well in a cell for the FEOL memory cell design, wherein the doped well is doped oppositely than a substrate of an IC to be fabricated based on the FEOL memory cell design; and
placing an inverter in a same circuit row of the cell as the latch.

13. The system of claim 12, wherein generating the FEOL memory cell design comprises:
determining that a combined length of the latch and inverter is less than a width of the cell; and
adding at least one read or write port to the same circuit row.

14. The system of claim 13, wherein generating the FEOL memory cell design comprises:
determining that no more read or write ports can be added to the same circuit row;
determining there are remaining read and write ports that should be added to the cell; and
adding the remaining read and write ports in one or more different circuit rows in the cell.

15. The system of claim 9, wherein the RC characteristics and the FEOL memory cell design are balanced when the RC characteristics of the metal routing layers in the BEOL design satisfy a performance threshold with current dimensions of the FEOL memory cell.

16. A computer program product comprising:
one or more computer readable storage media; and
program instructions stored on the one or more computer readable storage media to perform operations comprising:
generating, using an integrated circuit (IC) design application executing in a processor, a front end of line (FEOL) memory cell design, wherein the FEOL memory cell design is for a multiport memory cell;
designing, using the IC design application, metal routing layers in a back end of line (BEOL) design;
determining, using the IC design application, resistive-capacitive (RC) characteristics between the metal routing layers; and
upon determining the RC characteristics and the FEOL memory cell design are unbalanced, adjusting at least one of the metal routing layer or dimensions of the FEOL memory cell design.

17. The computer program product of claim 16, wherein the operations comprise:
fabricating an IC based on the metal routing layers in the BEOL design and the FEOL memory cell design.

18. The computer program product of claim 16, wherein generating the FEOL memory cell design comprises:
placing a latch in a doped well in a cell for the FEOL memory cell design, wherein the doped well is doped oppositely than a substrate of an IC to be fabricated based on the FEOL memory cell design; and
placing an inverter in a same circuit row of the cell as the latch.

19. The computer program product of claim 18, wherein generating the FEOL memory cell design comprises:
determining that a combined length of the latch and inverter is less than a width of the cell; and
adding at least one read or write port to the same circuit row.

20. The computer program product of claim 19, wherein generating the FEOL memory cell design comprises:
determining that no more read or write ports can be added to the same circuit row;
determining there are remaining read and write ports that should be added to the cell; and
adding the remaining read and write ports in one or more different circuit rows in the cell.
